(19) United States
(12) Patent Application Publication
(10) Pub. No.: US 2014/0252436 A1
(43) Pub. Date: Sep. 11, 2014

(54) SEMICONDUCTOR DEVICE

(71) Applicants: Tomoyuki Suwa, Sendai-shi (JP); Hiroaki Tanaka, Sendai-shi (JP); Tadahiro Ohmi, Sendai-shi (JP)

(72) Inventors: Tomoyuki Suwa, Sendai-shi (JP); Hiroaki Tanaka, Sendai-shi (JP); Tadahiro Ohmi, Sendai-shi (JP)

(73) Assignee: TOHOKU UNIVERSITY, Sendai-shi (JP)

(21) Appl. No.: 14/285,680

(22) Filed: May 23, 2014

Related U.S. Application Data
(63) Continuation of application No. PCT/JP2012/004428, filed on Jul. 9, 2012.

(51) Int. Cl. H01L 29/78; H01L 29/66

(52) U.S. Cl. CPC H01L 29/78; H01L 29/66507
USPC 257/288; 438/301

(57) ABSTRACT

There is provided a semiconductor device with basic electronic elements in a three-dimensional structure. The semiconductor device has a source region and a drain region each of which includes an electrode and a silicide region, and is formed with a plurality of different crystal planes. The silicide regions on different crystal planes of the source region and the drain region have different thicknesses.

This application is a continuation of International Patent Application No. PCT/JP2012/004428 filed on Jul. 9, 2012, the entire content of which is incorporated herein by reference.

### BACKGROUND OF THE INVENTION

1. Field of the Invention

The present invention relates to a semiconductor device.

2. Description of the Related Art

The history of the development of semiconductor devices such as an IC (Integrated Circuit) and LSI (Large-Scale Integrated circuit) has progressed mostly by micropatterning and high integration.

The dimension (particularly the gate length) of a basic electronic element, for example, a MOSFET (Metal Oxide Semiconductor Field Effect Transistor) as one constituent element of a semiconductor device has steadily been reduced, and micropatterning of basic electronic elements has been advanced in conformity with a so-called scaling rule. In addition, high performance has been attained by scaling.

Whenever the generation of micropatterning of basic electronic elements has progressed, various problems have arisen, but each problem has been solved every time. However, it has become impossible to unlimitedly increase the integration degree by micropatterning while ensuring the original characteristics of basic electronic elements by using the two-dimensional structure (planar structure) and two-dimensional array of the basic electronic elements.

Recently, the integration degree has further been increased by adopting a three-dimensional array structure obtained by multilayering using the multilayered wiring technique. Alternatively, a basic electronic element having a stereoscopic structure such as a FinFET has been adopted to prevent the deterioration of the characteristics of the element caused by micropatterning, thereby further increasing the degrees of micropatterning and integration.

On the other hand, for a basic electronic element such as a transistor, for example, a MOS transistor, an electrical contact between each source/drain region and a corresponding electrode is ideally an ohmic contact. Therefore, the technique of silicidation is generally adopted.

In a basic electronic element having a three-dimensional structure such as a FinFET by which a high function can be achieved by avoiding the deterioration of the element characteristics caused by micropatterning while further advancing micropatterning, the structure of a source/drain region has a multi-crystalline plane arrangement, and has a plurality of different crystal planes. An electrode is formed for each of these different crystal planes, and a silicide region is formed between this electrode and the source/drain region.

The silicide region formed for each of the different crystal planes has a function of minimizing the electric resistance of the path of an electric current flowing through the electrode, silicide region, and source region, and through the electrode, silicide region, and drain region, thereby improving the characteristics of a transistor to be formed.

When the basic electronic element has a certain size as before, the electrical resistance of the current path described above is not a serious problem. However, as the integration degree increases by micropatterning and the size of the basic electronic element decreases, the problem of the electrical resistance of the current path described above has become obvious.

The electrical resistance of the current path is roughly classified into a contact resistance between the electrode and silicide region, a contact resistance between the silicide region and each of the source region and drain region, and an internal resistance of each of the silicide region, source region, and drain regions.

When using a silicon wafer or SOI substrate as a semiconductor substrate, each source/drain region is a heavily doped region formed by heavily doping an impurity such as boron (B) or phosphorus (P) in an Si layer, and the silicide region is a region formed by causing a silicidation reaction between this heavily doped region and an appropriate metal. The internal resistance of each of the source region and drain region is reduced by properly selecting the material of an impurity to be doped and optimizing the doping amount. The contact resistance is reduced by proper selection of a metal and a proper silicidation process.

This element design protocol is also applied to a semiconductor device formed by basic electronic elements such as FinFETs each having a source region and drain region formed by a plurality of different crystal planes.

In addition, even in a basic electronic element such as a FinFET having a source region and drain region formed by a plurality of different crystal planes, silicide regions are equally formed regardless of the crystal planes, in the same process as in a basic electronic element having a two-dimensional structure in which a source region and drain region are formed by one crystal plane.

### SUMMARY OF THE INVENTION

According to an embodiment, a semiconductor device with basic electronic elements in a three-dimensional structure comprises a source region and a drain region each of which includes an electrode and a silicide region, and is formed with a plurality of different crystal planes, wherein the silicide regions on different crystal planes of the source region and the drain region have different thicknesses.

According to another embodiment, a semiconductor device with basic electronic elements in a three-dimensional structure comprises: a channel region having a plurality of different crystal planes; a gate electrode facing the plurality of crystal planes of the channel region; a gate insulating film between the gate electrode and the channel region; and a first and a second heavily doped region doped with semiconductor impurity facing with each other in a direction in which an electric current flows through the channel region and sandwiching the channel region; wherein each of the heavily doped region has a plurality of different crystal planes and has a silicide region directly formed on each crystal plane, and the silicide regions on different crystal planes have different thicknesses.

Other features and advantages of the present invention will be apparent from the following explanation taken in conjunction with the accompanying drawings. Note that the same reference numerals denote the same or similar parts in the accompanying drawings.

The accompanying drawings, which are incorporated in and constitute a part of the specification, illustrate embodiments of the invention and, together with the description, serve to explain the principles of the invention.

### BRIEF DESCRIPTION OF THE DRAWINGS

FIG. 1 is a schematic perspective view showing a typical example of a MOSFET having a three-dimensional structure of the present invention;

FIG. 2 is a schematic sectional view taken along a line A-A shown in FIG. 1;

FIG. 3 is a schematic sectional view taken along a line B-B shown in FIG. 2;

FIG. 4 is a first schematic step outline explanatory view showing an earlier step of step examples of a practical manufacturing method of an example of the MOSFET having the three-dimensional structure of the present invention;

FIG. 5 is a second schematic step outline explanatory view showing a middle step of the step examples of the practical manufacturing method of the example of the MOSFET having the three-dimensional structure of the present invention;

FIG. 6 is a third schematic step outline explanatory view showing a later step of the step examples of the practical manufacturing method of the example of the MOSFET having the three-dimensional structure of the present invention;

FIG. 7 is a step view for schematically explaining one typical example of the formation of a silicide region according to the present invention;

FIG. 8 is a step view for schematically explaining another typical example of the formation of the silicide region according to the present invention; and

FIG. 9 is a schematic sectional view for explaining another typical example of the MOSFET having the three-dimensional structure of the present invention.

### DESCRIPTION OF THE EMBODIMENTS

The present inventors have made extensive studies and obtained the findings that when the size of a basic electronic element becomes equal to or smaller than a certain size, the crystal plane dependence becomes obvious in a silicide region and increases as micropatterning of the basic electronic element advances, and, to further increase the degree of micropatterning, it is difficult for the conventional method as described above or for an extended version of the method to improve the performance of the basic electronic element, or to improve the performance of a highly integrated semiconductor device formed by integrating a large number of basic electronic elements.

Some embodiments provide a basic electronic element having essential element performance based on size design even when the size decreases, and an integrated semiconductor device formed by integrating the basic electronic elements.

Some embodiments provide a method of manufacturing a basic electronic element having essential element performance based on size design even when the size decreases, and a method of manufacturing an integrated semiconductor device formed by integrating the basic electronic elements.

Some embodiments provide a basic electronic element having a structure including a source region and drain region formed by a plurality of different crystal planes, and an integrated semiconductor device formed by integrating these basic electronic elements.

These problems are solved by forming an optimum silicide region on each crystal plane.

According to some embodiments, it is possible to obtain a basic electronic element having essential element performance based on size design even when the size decreases, and an integrated semiconductor device formed by integrating the basic electronic elements.

In the present invention, a term “semiconductor device” means one or both of the above-mentioned basic electronic element and an integrated semiconductor device formed by integrating the basic electronic elements hereinafter unless otherwise specified.

Practical examples of the present invention will be explained below, but the present invention is not limited to these examples.

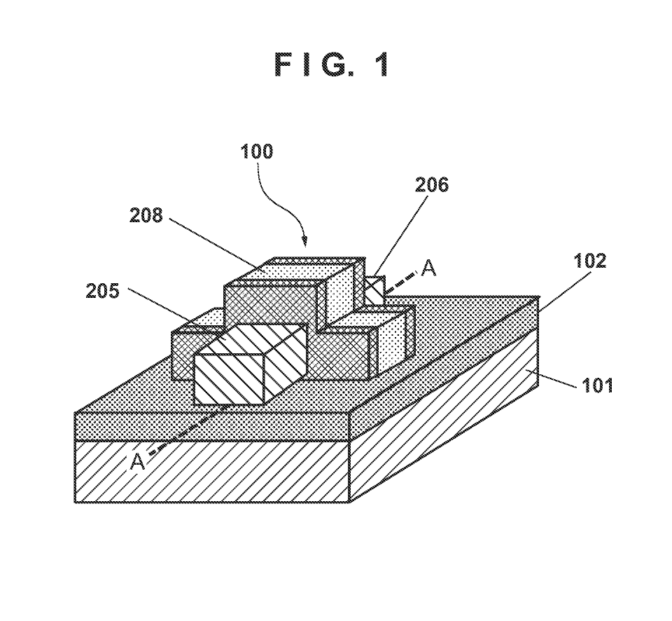

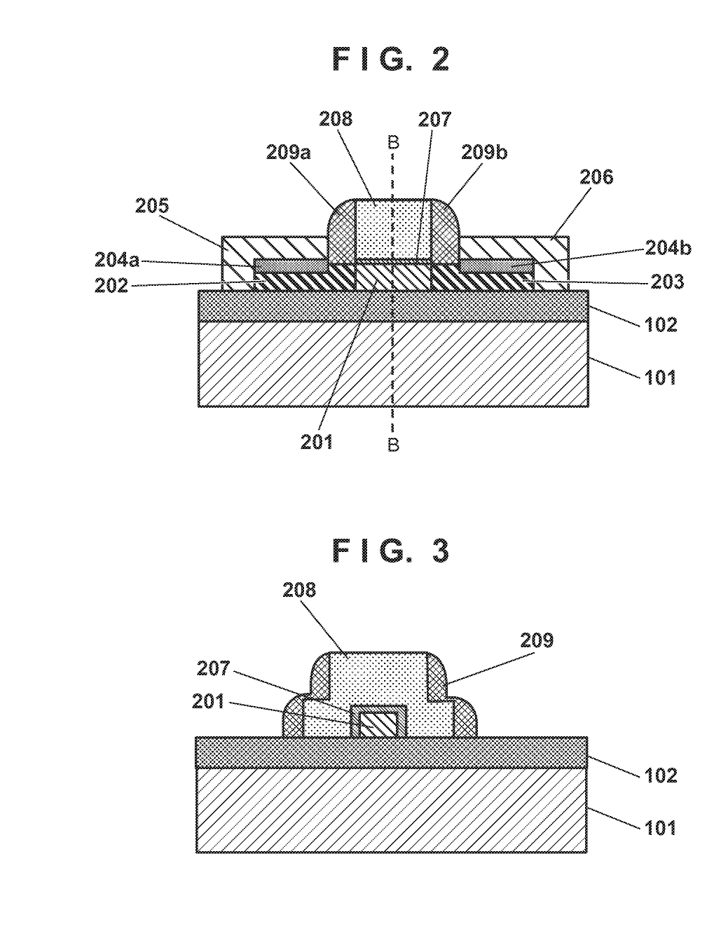

FIGS. 1, 2, and 3 show one typical example of a MOSFET 100 having a three-dimensional structure of the present invention. FIG. 1 is a schematic perspective view, FIG. 2 is a schematic sectional view taken along a line A-A shown in FIG. 1, and FIG. 3 is a schematic sectional view taken along a line B-B shown in FIG. 2.

The MOSFET 100 includes an SOI layer region 201 where a channel region (not shown) is to be formed, and a source region (n^{|} region) 202 and drain region (n⁺ region) 203 formed outside the SOI layer region 201.

A gate insulating film region 207 and gate electrode layer region 208 are formed on the upper surface of the SOI layer region 201.

Silicide regions 204a and 204b are respectively formed outside the source region 202 and drain region 203.

A source electrode 205 is formed in electrically direct contact with the silicide region 204a, and a drain electrode 206 is formed in electrically direct contact with the silicide region 204b.

The gate insulating film region 207 and gate electrode layer region 208 are formed not only on the upper surface of the SOI layer region 201, but also on the side surfaces of the SOI layer region 201 formed along a direction in which an electric current flows in a channel region to be formed in the SOI layer region 201. That is, the gate insulating film region 207 and gate electrode layer region 208 are formed on three surfaces of the outer surfaces of the SOI layer region 201 formed along the direction in which an electric current flows in the SOI layer region 201, so as to surround the SOI layer region 201.

The silicide regions 204a and 204b are each formed on an entire or substantially entire corresponding side surface of two side surfaces perpendicular or almost perpendicular to the direction in which an electric current flows in the SOI layer region 201, among the side surfaces of the SOI layer region 201, in an electrically direct contact state.

By thus forming the silicide regions 204a and 204b, a channel region to be formed in the SOI layer region 201 can be formed in an almost entire or substantially entire area of the SOI layer region 201.

### EXAMPLE 1

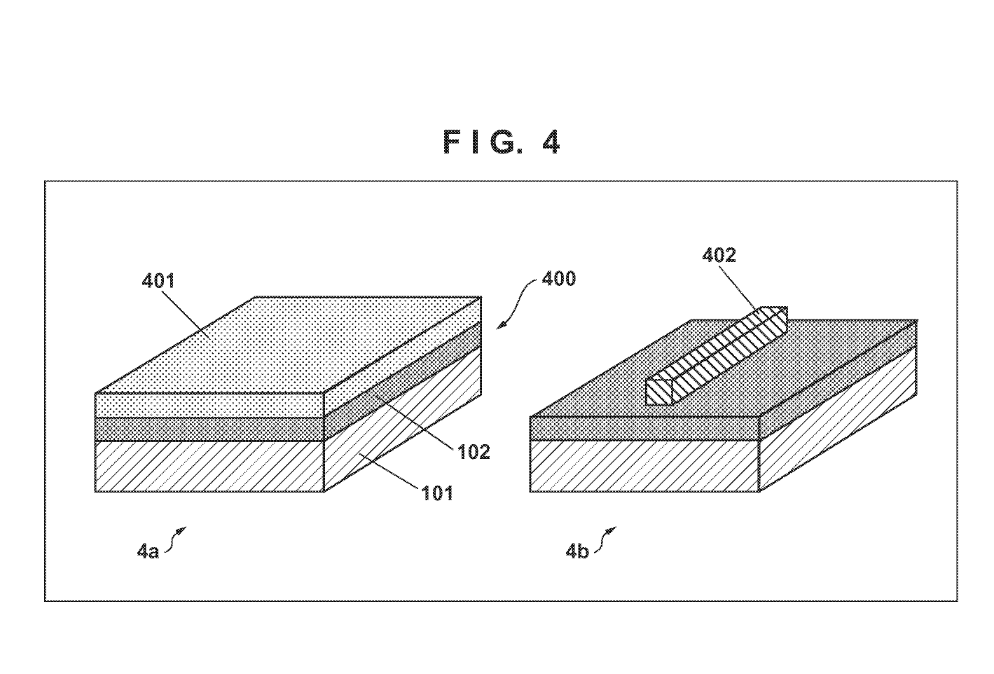

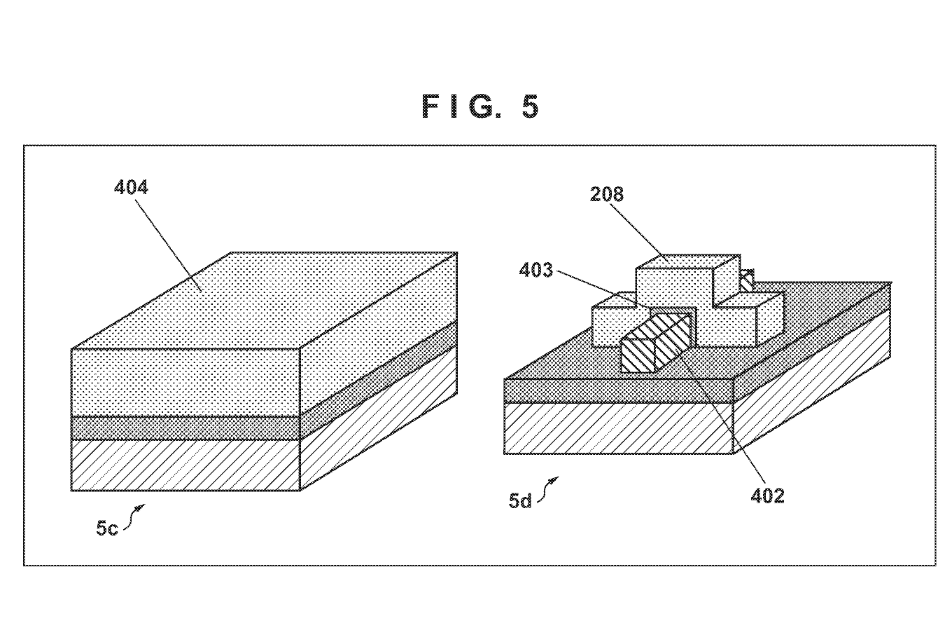

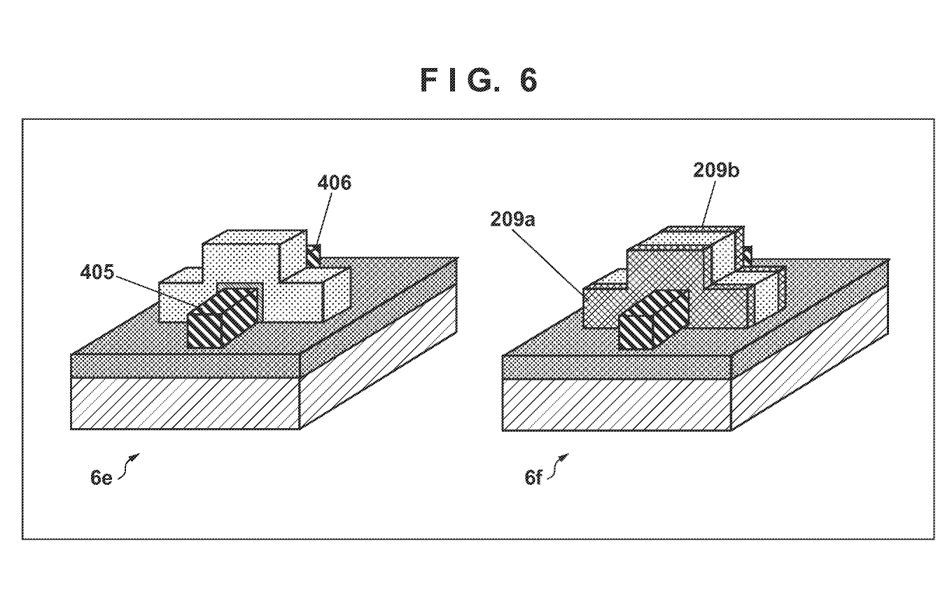

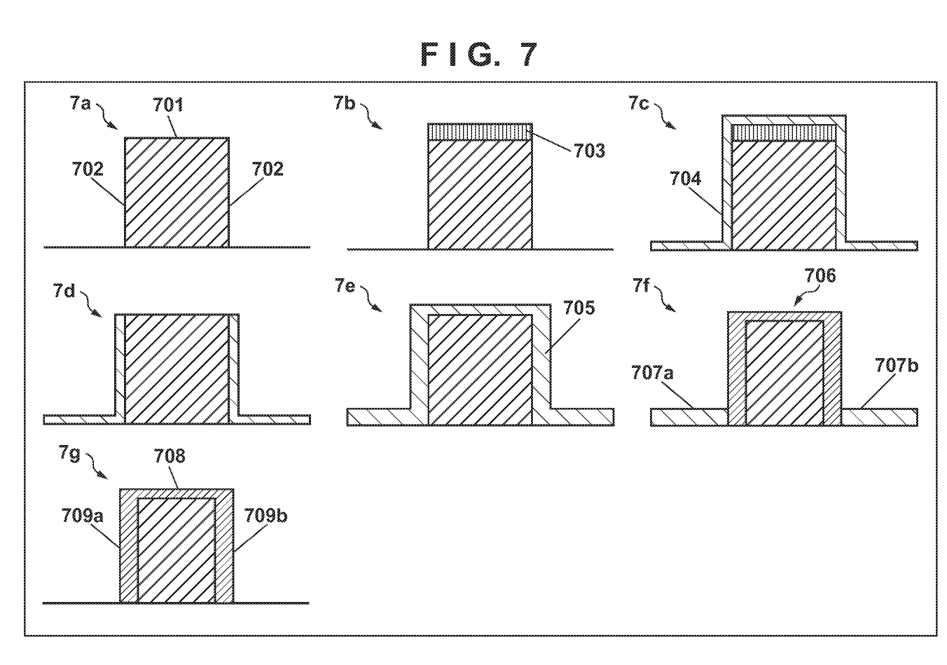

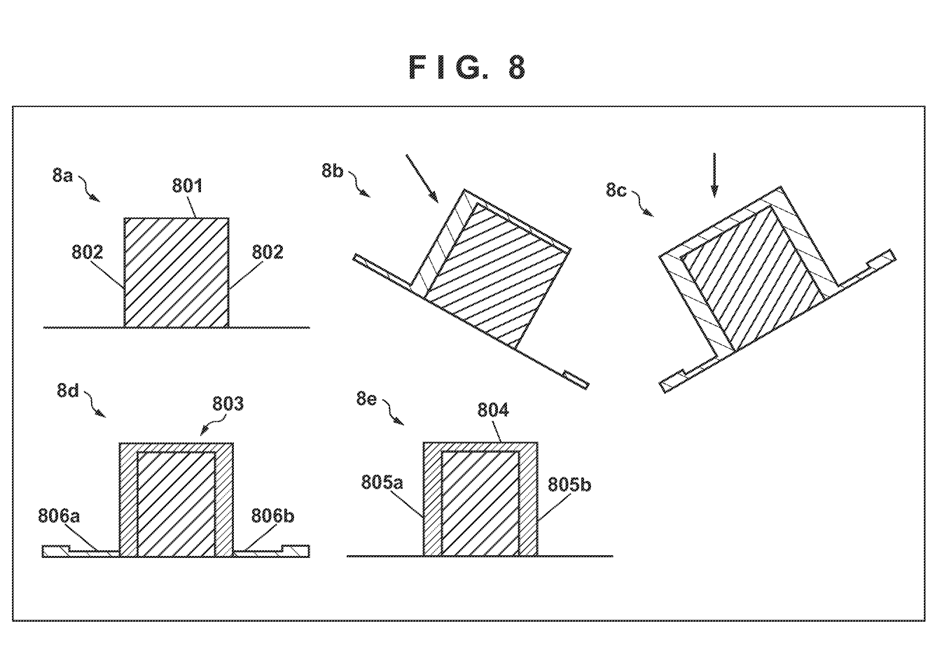

FIG. 4 is a first schematic step outline explanatory view showing an earlier step of step examples of a practical manufacturing method of an example of the MOS-FET having the three-dimensional structure of the present invention. FIG. 5 is a second schematic step outline explanatory view showing a middle step. FIG. 6 is a third schematic step outline explanatory view showing a later step. FIGS. 4, 5, and 6 are views for explaining steps before the silicide region 204 is formed. Note that FIGS. 7 and 8 illustrate favorable examples in which the silicide region 204 is formed on a predetermined crystal plane.

First, a base 400 for forming the MOS-FET having the three-dimensional structure of the present invention is prepared, and an SOI layer 401 is formed on the base 400 (“step (4a)” in FIG. 4). The base 400 includes a silicon substrate 101 and a BOX layer 102 formed on it.

Then, an SOI layer region a 402 is formed by etching a portion to be removed of the SOI layer 401 by dry etching or the like (“step (4b)” in FIG. 4).

After that, a gate insulating film (not shown) made of an insulating material such as SiO₂ and a gate electrode layer 404 are formed on the SOI layer region a 402 by deposition using sputtering and by normal patterning. The gate electrode layer 404 is made of, for example, poly-Si (“step (5c)” in FIG. 5).

After that, a gate insulating film region a 403 and gate electrode layer region 208 are formed by patterning by performing resist coating, pattern exposure, etching, washing, and the like (“step (5d)” in FIG. 5).

An impurity such as boron (B) is heavily ion-implanted into prospective source/drain regions of the SOI layer region a 402, thereby forming a source region layer 405 and drain region layer 406 as heavily doped n⁺ regions (“step (6e)” in FIG. 6).

Then, an insulating material such as SiO₂ is deposited by sputtering or the like, and anisotropically etched by dry etching, thereby forming sidewalls 209a and 209b as shown in FIG. 6 (“step (6f)” in FIG. 6).

The points of the steps (FIGS. 4 to 6) explained above will be summarized below.

Step (4a) Preparation of SOI Wafer

The film thickness of the SOI layer is adjusted to a predetermined value.

Step (4b) Isolation of SOI Layer Element

A pattern of an element isolation portion is formed by dry etching.

Step (5c) Formation of Gate Insulating Film and Deposition of Gate Electrode

A gate insulating film is formed by an insulating material such as SiO₂.

Poly-Si for a gate electrode is deposited.

Step (5d) Etching of Gate Electrode and Etching of Gate Insulating Film

A gate electrode layer region 208 is formed by dry-etching the gate electrode poly-Si (a gate electrode layer 404).

A gate insulating film region a 403 is formed by etching the gate insulating film (by dry etching or wet etching).

Step (6e) Ion Implantation into Source/Drain Region Layers

A semiconductor impurity such as boron (B) or phosphorus (P) is ion-implanted into the source/drain region layers, thereby forming impurity heavily doped region layers (a source region layer 405 and drain region layer 406).

Step (6f) Formation of Sidewalls 209

A thin sidewall formation film is deposited.

The thin sidewall formation film is dry-etched (anisotropically etched).

### SILICIDE REGION FORMATION EXAMPLE 1

Next, an example of silicide region formation will be explained with reference to FIG. 7. In steps (7c) to (7e) of FIG. 7, a metal layer b 705 for silicide formation is formed twice by vapor deposition as shown in FIG. 7. In these steps, vapor deposition is performed by selecting vapor deposition conditions such that the thickness of the silicide region is optimum for each crystal plane.

In the example shown in FIG. 7, the thickness of the metal layer b 705 on a (100) plane 702 is larger than that of the metal layer b 705 on a (551) plane 701. Accordingly, the thickness of a silicide region to be formed by a silicidation process to be applied later is larger on the (100) plane 702.

In the present invention, the thickness of a silicide region a 708 to be formed on the (551) plane 701 is preferably 4 nm or less, when the metal to be used in silicidation is, for example, eurobium (Er).

Then, the silicide region a 708 and silicide regions 709a and 709b are respectively formed by annealing in the interface regions between the metal layer b 705 and the source region layer 405 and drain region layer 406 (“steps (7f) and (7g)” in FIG. 7). Simultaneously, a source region 202 and drain region 203 are formed (see FIG. 2).

Then, unnecessary metal layers 707a and 707b (unreacted metal layers) that are not silicided in the above-mentioned silicidation process are removed (“step (7g)” in FIG. 7).

After that, a metal layer for contact formation is formed by depositing a metal for forming an electrical contact, and an unnecessary portion of the metal layer is removed by patterning, thereby forming a source electrode 205 and drain electrode 206 (see FIG. 2).

Of the steps explained above, examples of the formation conditions of the points of silicide region formation will be summarized below.

(a) A source/drain region having a three-dimensional structure is formed (step 7a in FIG. 7).

(b) The surface is coated with a resist by using a spin coater (step 7b in FIG. 7).

(c) A metal layer a 704 is formed by metal deposition (step 7c in FIG. 7).
Er (eurobium) is deposited by sputtering.
Sputtering conditions: Ar gas flow rate . . . 20 sccm
   Pressure . . . 133 Pa (1 Torr)
   Film thickness . . . 8 nm

(d) The resist and the metal on the resist are removed (step 7d in FIG. 7).

For example, the metal film is lifted off while removing the resist by using an organic solvent.

(e) A metal layer b 705 is formed by metal deposition (step 7e in FIG. 7).
Er (eurobium) is deposited by sputtering.
Sputtering conditions: Ar gas flow rate . . . 20 sccm
   Pressure . . . 133 Pa (1 Torr)
   Film thickness . . . 2 nm

(f) A silicidation process is performed (step 7f in FIG. 7).

Lamp annealing is performed at 600° C. for 2 min.

(g) An unreacted metal is removed (step 7g in FIG. 7).

SPM (H₂SO₄:H₂O₂=4:1) is applied for 30 sec.

### SILICIDE REGION FORMATION EXAMPLE 2

Next, another example of silicide region formation will be explained with reference to FIG. 8. To avoid complication, the points will collectively be described below.

(a) A source/drain region having a three-dimensional structure is formed (step 8a in FIG. 8).

(b) A base is inclined and metal deposition is performed by anisotropic deposition under the following conditions, thereby forming a metal layer in the same manner as in FIG. 7 (step 8b in FIG. 8).
An Er film is formed by sputtering.
Sputtering conditions: Ar gas flow rate . . . 20 sccm
   Pressure . . . 0.67 Pa (5 mTorr)
A 5-nm thick Er film is formed on a (100) plane, and a 1-nm thick Er film is formed on a (551) plane.

(c) The base is inclined and metal deposition is performed by anisotropic deposition under the following conditions, thereby forming a metal layer in the same manner as in FIG. 7 (step 8c in FIG. 8).
Sputtering conditions: Ar gas flow rate . . . 20 sccm
   Pressure . . . 0.67 Pa (5 mTorr)
A 5-nm thick Er film is formed on a (100) plane, and a 1-nm thick Er film is formed on a (551) plane.

By thus performing deposition twice, a 10-nm thick Er film is formed on the (100) plane, and a 2-nm thick Er film is formed on the (551) plane.

(d) Silicidation Process

Lamp annealing is performed at 600° C. for 2 min.

(e) Unreacted Metal Removal

SPM (H₂SO₄:H₂O₂=4:1) is applied for 30 sec.

An example in which a source electrode 205 and drain electrode 206 are formed will be described below.

(1) A metal (tungsten: W) layer for contact formation is formed.
A tungsten (W) film is formed by sputtering.
Sputtering conditions: Ar gas flow rate . . . 20 sccm
   Pressure . . . 1.33 Pa (10 mTorr)
   Film thickness . . . 100 nm

(2) An unnecessary portion of the contact formation metal (tungsten: W) layer is removed by dry etching.
W dry etching conditions: Ar gas flow rate . . . 100 sccm
   SF₆ gas flow rate . . . 20 sccm
   Pressure . . . 1.33 Pa (10 mTorr)
   RF power . . . 30 W

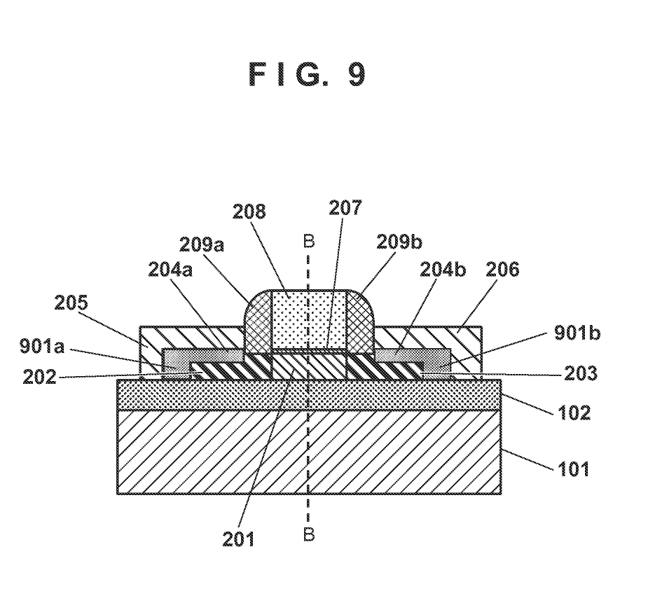

FIG. 9 shows an example in which silicide regions are formed on four surfaces of source/drain regions having a stereoscopic structure. This example shown in FIG. 9 is a modification of the example shown in FIG. 2. That is, although silicide regions are formed on three surfaces in the example shown in FIG. 2, silicide regions 901a and 901b are additionally formed in the example shown in FIG. 9. This structure can more reliably secure the current path.

The present invention is not limited to the above-described embodiments, and various changes and modifications can be made within the spirit and scope of the present invention. Therefore, to apprise the public of the scope of the present invention, the following claims are made.

### REFERENCE SIGNS LIST

100 FET
101 silicon substrate
102 BOX layer
201 SOI layer region
202 source region
203 drain region
204 silicide region
205 source electrode
206 drain electrode
207 gate insulting film region
208 gate electrode layer region
209 sidewall
400 base
401 SOI layer
402 SOI layer region a
403 gate insulating film region a
404 gate electrode layer
405 source region layer
406 drain region layer
407 upper-surface wall
701 (551) plane
702 (100) plane
703 resist film
704 metal layer a (silicide formation metal layer)
705 metal layer b (silicide formation metal layer)
706 silicided region
707 unnecessary (unreacted) metal layer
708 silicide region a
709 silicide region
801 (551) plane
802 (100) plane
803 silicided region
804 silicide region a
805 silicide region
806 unnecessary (unreacted) metal layer
901 silicide region

1. A semiconductor device with basic electronic elements in a three-dimensional structure, comprising a source region and a drain region each of which includes an electrode and a silicide region, and is formed with a plurality of different crystal planes, wherein said silicide regions on different crystal planes of said source region and said drain region have different thicknesses.

2. A semiconductor device with basic electronic elements in a three-dimensional structure, comprising:
a channel region having a plurality of different crystal planes;
a gate electrode facing the plurality of crystal planes of said channel region;
a gate insulating film between said gate electrode and said channel region; and
a first and a second heavily doped region doped with semiconductor impurity facing with each other in a direction in which an electric current flows through said channel region and sandwiching said channel region;
wherein each of said heavily doped region has a plurality of different crystal planes and has a silicide region directly formed on each crystal plane, and said silicide regions on different crystal planes have different thicknesses.

3. A method of manufacturing a semiconductor apparatus, comprising:
forming a source region and a drain region, wherein the semiconductor apparatus is with basic electronic elements in a three-dimensional structure comprising the source region and the drain region each of which includes an electrode and a silicide region, and is formed with a plurality of different crystal planes;
placing metal layers for forming silicide in different thicknesses, on the different crystal planes of the source and drain regions; and
forming silicide regions at interface regions between the source and drain regions and the metal layer by annealing.
